(19) United States
(12) Patent Application Publication
(10) Pub. No.: US 2018/0074240 A1
(43) Pub. Date: Mar. 15, 2018

(54) COLOUR CONVERTING STRUCTURE FOR LED ARRAYS

(71) Applicant: Oculus VR, LLC, Menlo Park, CA (US)

(72) Inventors: James Ronald Bonar, Erskine (GB); Paul Gregory Harris, Ruislip (GB); Gareth John Valentine, York (GB); Stephen Gorton, Edinburgh (GB); George Fern, Chalgrove (GB); Jack Silver, London (GB)

(21) Appl. No.: 15/565,668

(22) PCT Filed: Apr. 11, 2016
(86) PCT No.: PCT/GB2016/051000

§ 371 Date: Oct. 10, 2017

(30) Foreign Application Priority Data
Apr. 16, 2015 (GB) 1506486.8
Nov. 26, 2015 (GB) 1520894.5

(51) Int. Cl. G02B 5/20; H01L 33/50

(52) U.S. Cl. CPC G02B 5/201; H01L 33/504; H01L 33/507

(57) ABSTRACT

There is herein described a structure for converting light from LED arrays from shorter wavelength, for example blue, into longer wavelength light, for example red and green, so as to form displays containing red, green and blue sub-pixels. More particularly, the present invention relates to a structure and process in which light from LED arrays of the same wavelength is converted into alternate colours by means of a colour conversion structure.

### FIELD OF THE INVENTION

The present invention relates to a structure for converting light from LED arrays from shorter wavelength, for example blue, into longer wavelength light, for example red and green, so as to form displays containing red, green and blue sub-pixels. More particularly, the present invention relates to a structure and process in which light from LED arrays of the same wavelength is converted into alternate colours by means of a colour conversion structure.

### BACKGROUND OF THE INVENTION

There are of course many ways in which RGB displays can be made. For example, cathode ray tubes were manufactured by depositing arrays of cathodoluminescent phosphors to convert the electron beam into red, green and blue light. These pixels were typically formed by screen-printing or by incorporating the phosphor particles into a photoresist (normally dichromated polyvinyl alcohol) that could be patterned by photolithography and subsequently burnt out. In comparison with the devices of interest in this work these pixels were substantially larger, however, and the inevitable loss of spatial resolution due to the scattering of the radiation used to cure the photoresist was not a major issue, but it becomes a major problem if you attempt to reduce the dimensions of the sub-pixels, for example to below 10 μm. Similarly screen printing is limited to pixel sizes >100 μm.

Another approach is to use red, green and blue emitting LEDs in a discrete manner. The disadvantage with this approach is the techniques to pick and place individual LEDs of dimensions <50 μm to provide the discrete wavelength operation in a display with pixel pitch of <100 μm. Although, there are advantages with regards spectral purity, selection of working pixels prior to bonding and display efficiency there is the need to use three different compound semiconductors. Consequently, there are disparate materials which have different properties with varying electrical characteristics and physical dimensions which need to be carefully tailored. A major issue is the selection of green LED devices. It is necessary to have a small chromatic variation over drive current and temperature. Thus, for each green LED emission the wavelength needs to emit within a tight distribution. The user's eye is very sensitive to small variations in wavelengths near the peak of its visual response. There are also practical issues relating to time, cost and complexity of flip-chipping such small devices.

An alternative approach is to use the primary (e.g. blue) light from an array of LEDs to excite a yellow emitting phosphor such as cerium doped yttrium aluminium garnet (YAG:Ce) so as to produce a pseudo-white by mixing the blue and yellow. Colour filters can then be used convert this emission into red, green and blue components. An advantage of this approach is that it is not necessary to pattern the phosphor layer. There are unfortunately a number of serious drawbacks to this approach. Using colour filters to subtract out unwanted portions of the spectrum is wasteful of light. As an example, approximately 60 to 70% of the spectral range of the white pixels is lost/not needed to achieve the colour gamut in a RGB display. The YAG:Ce emission is also quite weak above 630 nm, which reduces the colour gamut obtainable. Both of these factors mean that to obtain sufficient light output you must run the device at higher powers which causes a reduction in efficiency and increased power demand (hence shorter battery life). There is also likely to be substantial cross-talk between pixels, reducing colour gamut and spatial resolution.

Conventional liquid crystal (LCD) displays operate by a similar route. They form RGB displays by using liquid crystal arrays to control the intensity of light, emitted from a mixture of photoluminescent (PL) phosphors that is transmitted to colour filters. In this case the phosphor is not patterned into pixels, only the colour filters and the LCD array. The PL phosphors in this case are excited using UV light and this permits alternate phosphors to be used and a better quality of white emission to be generated. As with the LED-YAG:Ce devices, the approach is subtractive and less efficient than the discrete LED approach. The liquid crystal “pattern generator” located externally to a light source is permanently on full brightness, and consequently this type of display requires extra components. As mentioned a further basic drawback then relates to the power loss as all pixels must be addressed with light even if they are not used to display the image. Typically, only 20% of pixels are on when viewing a typical graphical video display. The contrast ratio of such displays is also compromised. These drawbacks are extremely serious for mobile enabled devices such as augmented reality, virtual reality, smart watches, smart phones, etc.

It is an object of at least one aspect of the present invention to obviate or mitigate at least one or more of the aforementioned problems.

It is a further object of at least one aspect of the present invention to provide a process in which light from LED arrays of the same wavelength is converted into alternate colours by means of a colour conversion structure.

### SUMMARY OF THE INVENTION

According to a first aspect of the present invention there is provided a process for forming a colour converting structure for use in conjunction with LED arrays comprising the steps of forming wells within or on a transparent substrate, depositing luminescent materials in the form of an ink with a suitable binder onto the colour converting structure and removing excess ink and wherein the colour converting structure is capable of converting UV or blue light from the LED into other wavelengths (i.e. colours) in the visible spectrum.

Generally speaking, the present invention therefore resides in the provision of a process in which light from LED arrays of the same wavelength is converted into alternate colours by means of a colour conversion structure. The advantage in converting to discrete colours rather than into white is that only light in the correct spectral region is created, and this is much more efficient than, for example, converting into a pseudo white and then filtering out most of the light you have created in order to create discrete colours.

The colour converting structure may be for display purposes.

The LED arrays may be micro-LEDs.

The excess ink may be removed using any suitable technique such as using a doctor blade.

Typically, the wells may be defined using a photolithographic process. The wells may be defined using a physical process such as reactive ion etching to transfer the photolithographically defined structure into the transparent substrate.

The wells may be defined using a physical process such as reactive ion etching to transfer the photolithographically defined structure into a separate layer or layers on the transparent substrate.

In an alternative, the colour converting structure may be at least partially fabricated using microwaves which can be used to locally heat parts of the structure. The microwaves may induce rotation of H atoms in water or organic particles, or by interacting with materials that contain dipoles or pure metal structures that may spark on being exposed to microwaves.

The luminescent material contained in the wells may be either all or selectively patterned using a curing technique.

Typically, the binder may be UV curable, and can be exposed via a mask such that after development the luminescent ink may only be retained in specific wells.

The binder may be UV curable, and may be exposed via a direct write approach such that after development the luminescent ink is only retained in specific wells.

The ink used in the process may be photosensitive.

The wells may be filled in any appropriate manner and sequentially filled with appropriate inks.

The photosensitive material may be positive or negative photoresist.

Prior to deposition of the luminescent material the internal surface of the walls of the wells (but not the front window) may be coated in a reflective material, such as a metallisation or high refractive index material.

Prior to deposition of luminescent material the well structure may dyed so that the wells absorb light.

The well structures may be selectively dyed to absorb light of certain frequencies.

The luminescent material may be made from phosphor, quantum dot, organic substance or a combination thereof

Colour filters may be provided photolithographically between the recessed structure and the transparent substrate, using either coloured photoresist layers or transparent photoresist deposits that are subsequently dyed in-situ.

The colour filters may be thin film dielectric layers.

Sub-pixels may be formed which are grouped together so as to form channels e.g. 3×1 etc.

The sub-pixels may be grouped together so as to form groups of sub-pixels (e.g. 2×2). Alternatively, the sub-pixels may be form a group of sub-pixels in a display type configuration.

The configuration of the sub-pixels may be configured to optimise performance. For example, red light consumes a significant amount of energy and the configuration may therefore be adapted to reduce the amount of red light.

The conversion material may contain more than one type of luminescent material drawn from conventional (coarse) phosphors, Quantum Dot phosphors and luminescent dyes.

The well structure may be made from any appropriate material such as metal.

In a further embodiment of the invention, prior to deposition of any overlayers, the surface of the transparent sheet may be roughened using an etching process. The objective of the roughening process may be threefold. It may improves adhesion between the transparent substrate and any subsequently deposited layers. In the case of the phosphor filled channels tailoring the coarseness of the surface morphology to the particle size of the phosphor improves optical coupling and hence light extraction from the phosphor. In the case of the open blue channel, the roughening ensures that the angular distribution of the blue light, which is emitted directly from the micro-LED, more closely matches the dispersion obtained from the phosphor containing (red and green) sub-pixels. This is important so that there is no change in colour coordinates with viewing angle.

Any roughening process known in the art may be used to texture the surface. Various products are commercially available (for example from www.armourproducts.com) based upon baths or pastes that contain or generate hydrofluoric acid for etching glasses. Alternatively, it is known that caustic alkali solutions (such as sodium hydroxide solution) with concentration greater than 2 normal etch many glasses. Physical etching processes are also applicable such as grit blasting or mechanical abrasion such as using silicon carbide papers.

In a further refinement the adhesion of photoresist and inks may be further improved by treating the surface of the sheet with a silane coupling agent. Ideally the nature of the coupling agent used is tailored to the chemistry of the photoresist used.

This process is well discussed in the technical literature and various commercial companies supply ranges of different silane compounds that they recommend for specific resin chemistries.

According to a second aspect of the invention there is provided phosphor particles deposited into wells within a substrate and heat treated in-situ so as to improve their quantum efficiency and/or cause them to fuse together.

Rapid thermal annealing may be used to anneal phosphor particles.

A key feature of the present invention is the selection of colour conversion materials that are capable of carrying out this function efficiently.

Three types of material may be used to convert short wavelength light into longer wavelengths: conventional (coarse) phosphors (which usually have particle sizes >1 μm, and typically >10 μm), quantum dot phosphors (which usually have particle sizes <1 μm, and where the emission colour is determined by particle size) and luminescent dyes.

To work efficiently it is preferred luminescent dyes are fully dissolved in compatible resins in monomeric form and therefore in principle have the ability to be deposited at high resolution. In order to work these dye solutions normally have to be quite dilute as they lose quantum efficiency at higher concentrations and so relatively thick layers (e.g. >30 μm) of the dye containing deposit must be used to achieve full conversion. Organic dyes have numerous other drawbacks. They are notoriously unstable, particular when exposed to either elevated temperatures (as is often the case with LEDs) and/or the UV component of sunlight. Most also have relatively small stoke's shifts, which makes the achievement of blue to red conversion problematic.

Quantum dot phosphors are a relatively new development, and by virtue of their small size have in principal the ability to be patterned at high spatial resolution. At present, however, they are still under development and their properties, particularly longevity, are not completely understood. They can have high quantum efficiencies, but most of the best performers tend to be based upon highly toxic materials such as cadmium compounds, which are not acceptable in some applications. Their efficiency also depends on their physical form, because they suffer from serious self-absorption problems. In order to get complete conversion there is a need to use multiple layers of QDs and due to self-absorption they will be much less efficient than a single particle or a dispersed monolayer. Another drawback with QDs is that they saturate at relatively low light fluences, and this is a problem for micro-LED devices where the fluences can be extremely high. At present they are also extremely expensive, e.g. >1000 times the price of typical phosphors.

In the present invention it has been surprisingly found that conventional phosphors have a number of key advantages. They are comparatively cheap compared to QDs, and often have low toxicity. They are able to withstand high fluences of light without saturating and suffer less from self-absorption. They can have very high quantum efficiencies, and are not normally damaged by the UV in sunlight.

The problem to be addressed in this case, however, is how to pattern relatively coarse phosphor particles into the small sub-pixel sizes that are required to convert micro-LED arrays into red, green and blue displays. As discussed above, screen-printing has inadequate spatial resolution, as do other printing techniques such as gravure, flexography and offset lithography. Ink-jet printing has adequate spatial resolution, but generally requires particles of less than 1 μm maximum size. Incorporating photoluminescent phosphor particles into photoresist, with a sufficient volume fraction to facilitate adequate conversion, results in an unacceptable loss of spatial resolution.

At the same time it is necessary to control cross-talk between the sub-pixels and to prevent converted light from one pixel being re-scattered from another area of the device so that to an observer it apparently originates from the secondary scattering site. Worse still it is important to stop primary (e.g. blue) light escaping from one sub-pixel and exciting the wrong colour in adjacent sub-pixels.

According to a third aspect of the present invention there are products formed according to the first and second aspect.

A range of products may be formed using the present invention such as any of the following: micro-displays; wearables (e.g. phones, glasses, watches); mobile type displays; tablets; head-mounted displays; head-up displays (e.g. in automobiles and aircraft) and pico-projectors.

### BRIEF DESCRIPTION OF THE DRAWINGS

Embodiments of the present invention will now be described, by way of example only, with reference to the accompanying drawings in which:

FIG. 1 is a cross-section of a transparent sheet and wells filled with ink according to an embodiment of the present invention;

FIG. 2 is a top view of the transparent sheet with the wells filled with ink as shown in FIG. 1;

FIG. 3 is a representation of a transparent sheet with colour filter structures deposited thereon according to a further embodiment of the present invention;

FIG. 4 is a representation of a transparent sheet where well structures are formed by etching according to a further embodiment of the present invention;

FIG. 5 is a representation of a transparent sheet where well structures are coated in a highly reflective material, such as aluminium or a high refractive index material;

FIGS. 6 and 7 represent sub-pixels that are joined together so as to form channels of sub-pixels of the same colour according to further embodiments of the present invention;

FIG. 8a represents a deposition of a conductive film onto a transparent substrate followed by deposition of a patterned metallic matrix structure according to a further embodiment of the present invention; and

FIG. 8b represents wells in a metallic matrix structure filled with luminescent ink formulations according to a further embodiment of the present invention.

### BRIEF DESCRIPTION

Generally speaking, the present invention resides in the provision of a structure and process in which light from micro-LED arrays of the same wavelength is converted into alternate colours by means of a colour conversion structure.

In the present invention a transparent sheet 1 is made of, for example, a glass, sapphire or a polymeric sheet material such as polycarbonate or polymethylmethacrylate may be spin-coated with a layer of a negative photoresist such as SU-8 and pre-baked according to the instructions given by its supplier (MicroChem Inc.).

A matrix structure may then be exposed in the photoresist via a suitable mask. After development an array pattern of apertures may be formed, bounded by the matrix structure formed from the photoresist. These apertures in the photoresist layer form wells 4 which may then be filled with a suitable ink containing luminescent material. The luminescent ink may be formed by mixing luminescent materials with, for example, a suitable resinous binder. This binder may be most suitably a UV-curable resin. The luminous material can be a conventional phosphor such CaS:Eu, or Y₃(Ga,Al)O₁₂:Ce (supplied by Phosphor Technology Ltd), or quantum dot phosphors (e.g. supplied by Sigma-Aldrich). It can also be a luminescent dye material, such as supplied by Shanghai Keyan Phosphor Technology Co., Ltd.

The first ink 2 is dispensed onto the photoresist structure 1 so as to fill the wells 4 in the coating. Excess ink is then wiped off the structure 1 using any suitable device such as a doctor blade. A suitable doctor blade might be a rigid blade, for example made from polyurethane, or a flexible squeegee blade made from a rubber with a Shore (A) hardness of, for example, 70.

After applying the ink 1, the UV-curable binder is exposed via a mask to set the ink in those wells 24 where this particular colour is required. Uncured ink in other wells in the structure is the washed out using a suitable solvent such as isopropyl alcohol.

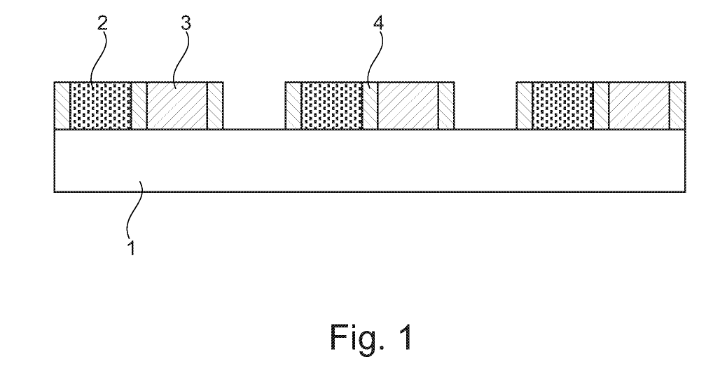

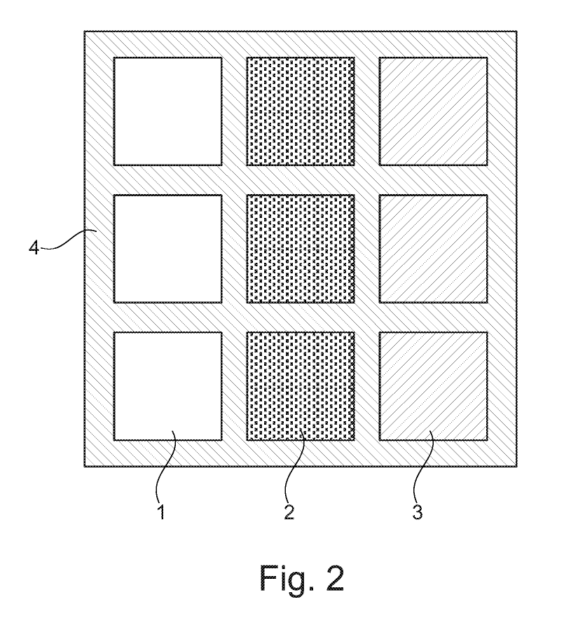

The process is then repeated using a second luminescent ink 3, formulated to give a different colour luminescence to the first (either red or green as appropriate). At the end of the process arrays of channels are provided with each pixel containing sub-pixels for converting blue light from the micro LED into red and green together with an open sub-pixel to provide a blue component. FIGS. 1 and 2 illustrate the structure formed. In this 1 is the transparent sheet, 2 and 3 are the luminescent inks and 4 is the matrix structure formed from photoresist.

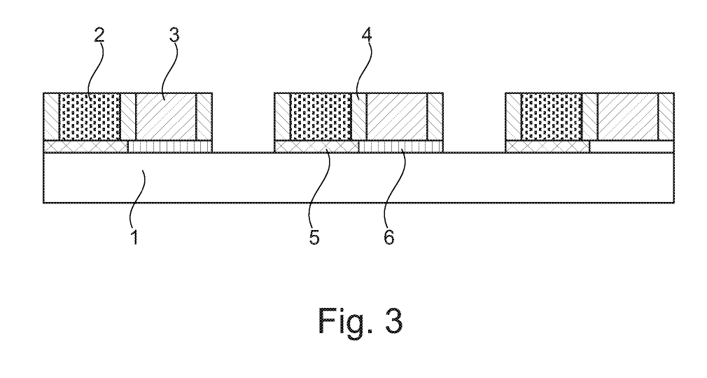

In a second embodiment of the invention, prior to forming the well structure, colour filter structures 5, 6 are deposited onto sheet material 1, and then the well structure formed on top of them as illustrated in FIG. 3. The advantage in this approach is that any unconverted blue light in the green and red sub-pixels can be filtered out before it leaves the structure. Additionally, the filter structures 5, 6 can narrow the broad emission bands of the phosphors, and although this reduces overall brightness, it substantially improves the colour gamut obtainable.

The colour filter structures 5, 6 are conveniently formed using coloured negative photoresist products known in the art, for example as supplied by the Fujifilm Corporation. This can include a red filter in front of the red luminescing sub-pixel, and a green filter in front of the green. Alternatively, a single blue absorbing layer can be placed in front of both, if the only objective is to remove unconverted blue light. This single colour layer can conveniently be deposited as described above, or by depositing SU-8 and dyeing it in-situ using a suitable water-borne disperse dye such as those well known in the art for dyeing polyester clothing.

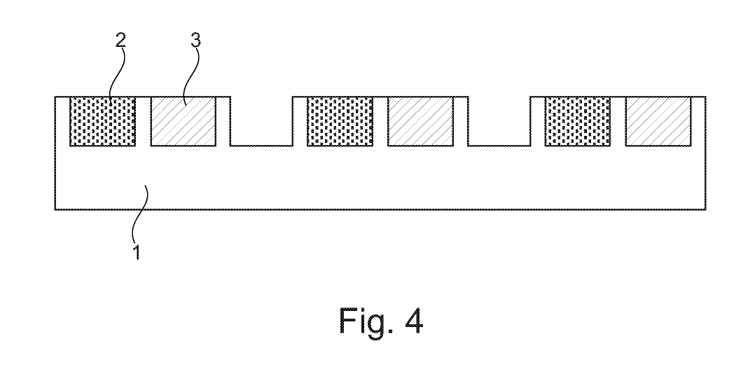

In a third embodiment of the invention, the well structure 4 is formed by etching the well structure into the sheet material 1 itself, as illustrated in FIG. 4. This can be accomplished by defining the matrix structure in photoresist as described above, followed by etching of the substrate 1 using any convenient means known in the art, such as reactive ion etching, wet chemical etching or grit blasting.

In order to achieve the sub-pixel sizes necessary for the smallest of these devices it can be necessary to mill phosphor particles down to very small sizes e.g. <1 μm. Milling phosphors unfortunately introduces large numbers of defects into their crystalline structures, which substantially deactivates them. They need to be annealed at high temperatures to reactivate them, and this often causes them to fuse together into clumps that are no longer of small enough size to deposit successfully. An advantage of creating wells in the substrate is that the binder may be burned out at low temperatures (e.g. 450° C.) and then the phosphor particles reactivated by high temperature (e.g. >1000° C. for 1 hour) heat treatment in-situ, advantageously with a controlled atmosphere e.g. with (in the case of sulphide phosphors) sulphurous species in the atmosphere to minimise sulphur loss. Moreover, it has been found that substantial reactivation can be achieved using rapid thermal annealing, in which the materials are ramped to high temperature within a few minutes, held at this temperature for a short period (e.g. 5 minutes or less) and then cooled quickly, and that this reduces the requirements for controlled atmospheres, so that merely inert (e.g. nitrogen) atmospheres can be sufficient.

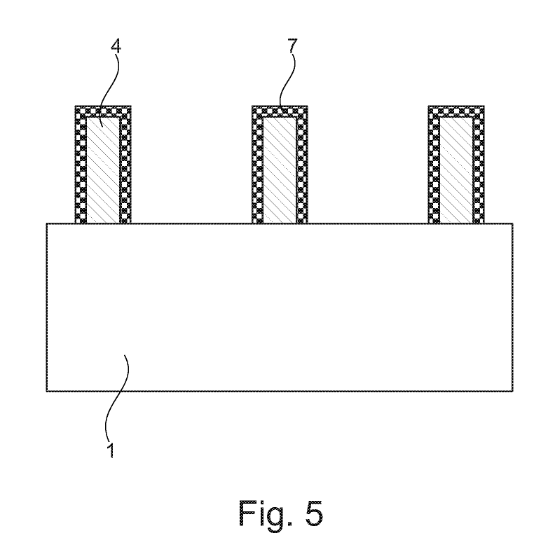

In a fourth embodiment of the invention after defining the well structure 4 the sidewalls of the wells 4 are coated in a highly reflective material, such as aluminium or a high refractive index material, as illustrated in FIG. 5. If an opaque material such as aluminium is used then it is important that the bases of the well structure 4 are not coated since this would prevent the light from exiting the structure. This can be conveniently achieved by coating using a physical deposition process, such as evaporation, at an oblique angle, so that the bases of the wells are shadowed and therefore not coated. To ensure that all walls are coated the operation can be repeated multiple times with the structure being rotated so as to expose each wall sequentially. In the case of square or circular sub-pixels the structure can be rotated continuously during a single deposition run. The advantage of doing this is that cross-talk between the pixels can be substantially reduced.

In a fifth embodiment of the invention, after creating the matrix from photoresist a suitable dye is used to colour it, in-situ, so that any blue light leaving one sub-pixel is absorbed before it reaches the adjacent pixel. Again the objective in so doing is to minimise cross-talk between pixels. This approach may be used on its own or in addition to the deposition of reflective material on the side-walls as described above.

In a sixth embodiment the well structure 4 is formed using a positive resist. Initially, only those sub-pixels required for a specific colour conversion are exposed and developed so as to form wells 4. These are then filled as before. Subsequently, the second set of colour conversion sub-pixels are exposed and developed and filled with the second ink as before. An advantage of this approach over that described above is that it is necessary to remove and recycle less of the expensive luminescent ink.

In the above embodiments each sub-pixel is isolated from all adjacent sub-pixels. For very small pixels this imposes strict limits on the maximum particle size that can be used. Often, larger phosphor particles are more efficient than smaller ones and so this restriction of their maximum size is unfortunate.

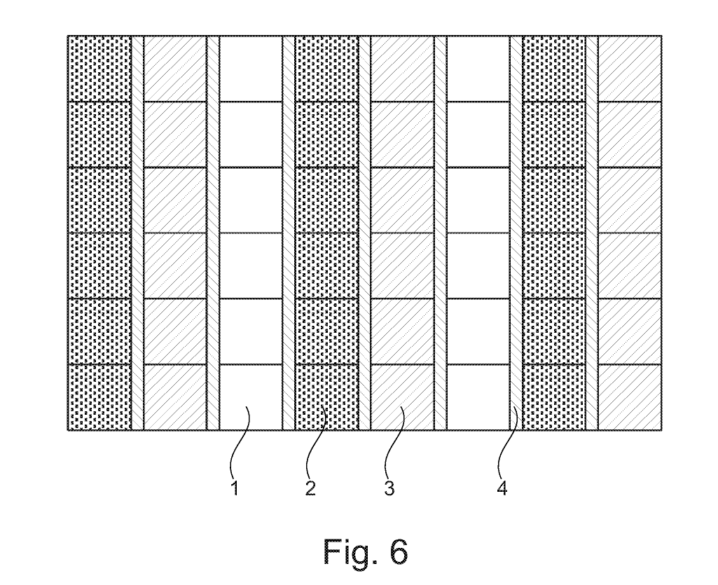

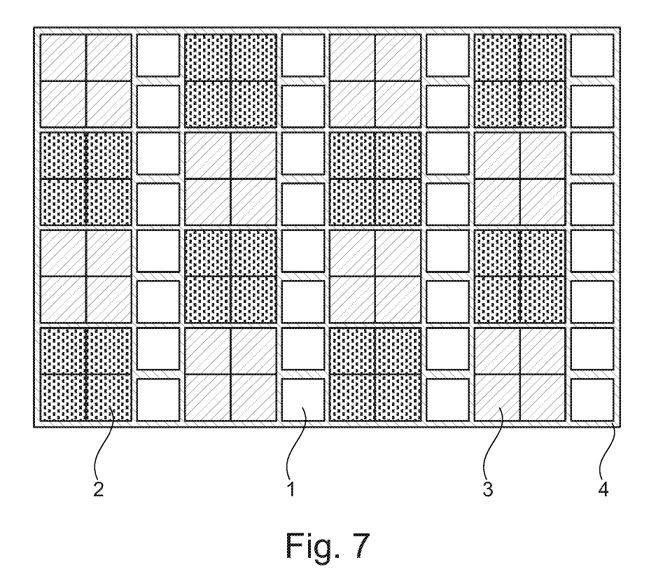

In a seventh embodiment of this invention, any of the embodiments described above may incorporate sub-pixels that are joined together so as to form channels of sub-pixels of the same colour, or 2×2 groups or any other type of groups of sub-pixels of the same colour as illustrated in FIGS. 6 and 7. The advantage of so doing is that the combined well structures can accommodate much larger particles, and this increases brightness, albeit at the expense of slightly higher levels of cross-talk.

Quantum dots (QDs) have advantages for this application of spectral purity and high extinction coefficients. They suffer from a significant disadvantage, however, which is that that they lose efficiency at high light fluences. Similarly, luminescent dyes have beneficial properties, but suffer from the disadvantage that they are degraded quite quickly by exposure to the UV from sunlight. In a further embodiment of this invention, one way to benefit from the good properties of QDs and or luminescent dyes while minimising the drawbacks of using these materials is to use a combination of both conventional phosphors with either QDs and/or luminescent dyes. The presence of substantial quantities of phosphors attenuates the LED light so for the most part the QDs are not over-driven. By the same token the phosphor absorbs and scatters the UV from sunlight strongly thus protecting the luminescent dye materials.

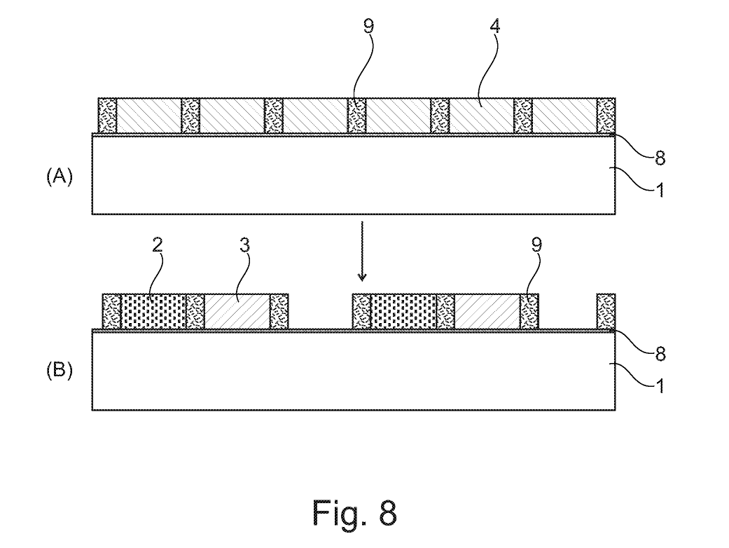

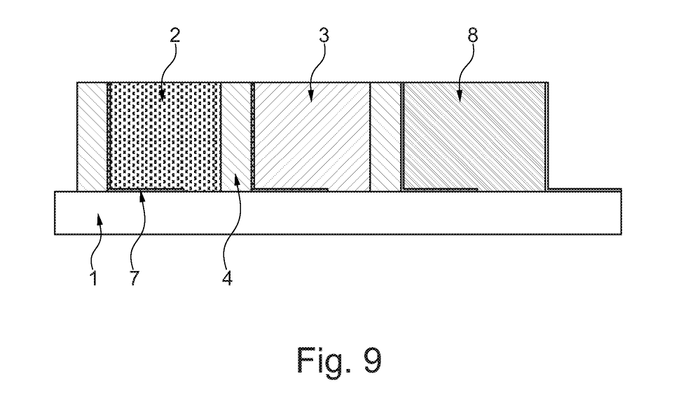

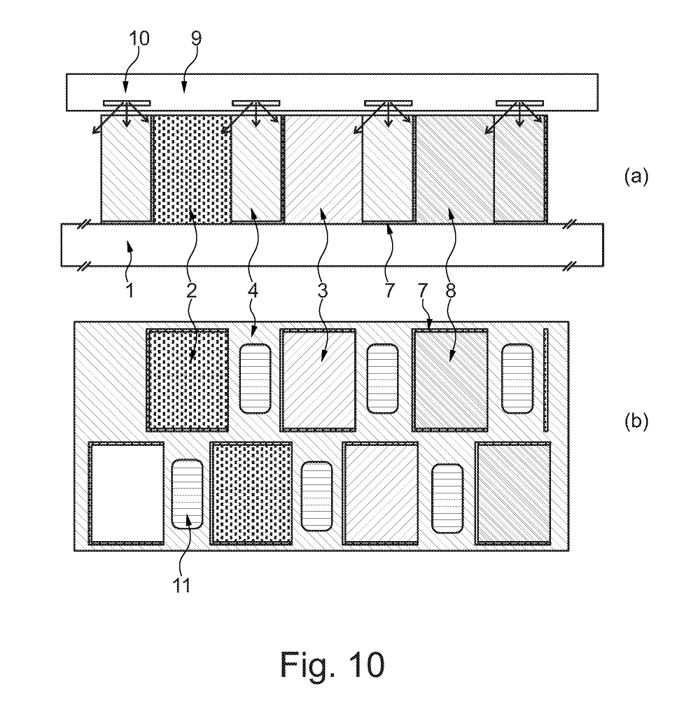

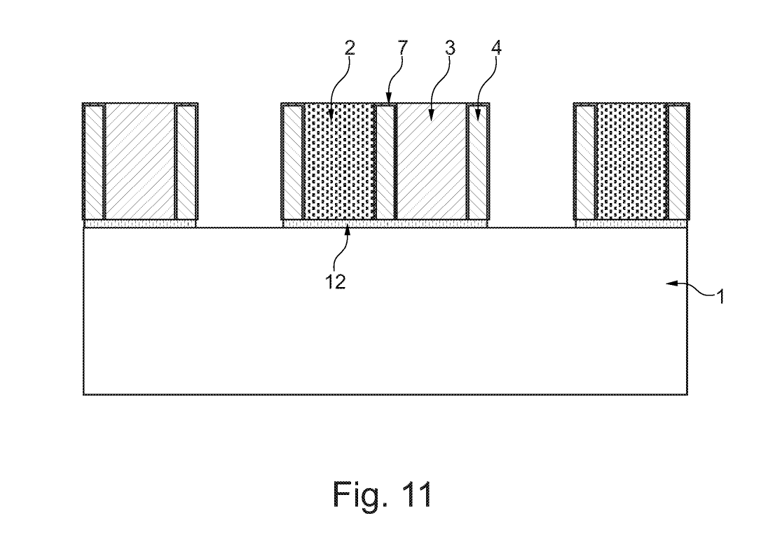

In a further embodiment of the invention, the well structure is constructed from a metallic material. There are several ways in which this can be achieved. One approach is illustrated in FIG. 8 (a) and involves the deposition of a conductive film 8 onto a transparent substrate 1. Alternatively, the layer can consist of a seed layer for an electroless deposition process. The seed layer may consist of a mixed stannous tin compound and a palladium compound. Numerous seed layer and bath chemistry formulations for electroless deposition are known in the art and can be obtained from a number of commercial supply houses.

The photoresist 4 is then applied and patterned so as to expose areas of the conductive/seed layer, which is then metallised 9 by either an electrolytic or electroless plating process, as illustrated in FIG. 8a. The photoresist is then removed. If the initial conductive layer was an opaque material (such as a thin metallic coating) then this must be removed from the base of the wells 4, by any means known in the art, such as sputtering or wet chemical etching. If it were a transparent material (such as indium tin oxide or fluorine-doped tin oxide) then this step is not necessary. Once the photoresist 4 and any opaque layer on the base of the well 4 has been removed, the wells 4 are filled with a luminescent ink formulations 2, 3 using any of the doctor blade processes describe above, forming the structure illustrated in FIG. 8(b).

An alternate technique for forming this metal matrix structure involves depositing and patterning photoresist 4 on the transparent substrate 1, in this case without a pre-coating of conductive material or electroless seed layer. The photoresist is ideally exposed so as to have inward sloping walls, as is well known in the art and is used in ‘lift-off’ processes. A metallisation layer is then applied by a physical deposition method such as evaporation or preferably sputtering. The metallisation is then thickened to the required depth using a plating process as described above. A preferred embodiment would be an initial coating, perhaps 10 nm thick of an adhesion promoter such as titanium or chromium, followed immediately by a further 20-50 nm of nickel to act as a basis for electroless (autocatalytic) deposition.

If an electrolytic plating process is used then care must be exercised to ensure the deposits are not highly stressed. A preferred embodiment would be to deposit nickel from a nickel glutamate bath, since these tend to use no addition agents and have low internal stress. Such bath chemistries are well known in the art and can be obtained from various commercial supply houses. Electroless nickel-phosphorous deposits are also low in stress, and again can be advantageously used. Silver may also be used as the initial layer and the bulk metal material and has the advantage of improved conductivity (an advantage when the coating is thin) and improved reflectivity compared to nickel. Disadvantages with silver, however, include higher cost, higher internal stress levels, and its propensity to tarnish. An alternative is to use either nickel or copper with a thin (<0.5 μm) coating of decorative chromium to enhance reflectivity (and hence to minimise absorption losses). Process chemistries for achieving this have been published and widely used in industry for many years.

In a further embodiment of the invention, two opposing walls of the wells are coated in a reflective material such as a metal, using any process known in the art (such as angled evaporation or sputtering). Aluminium is a particularly advantageous material, being easy to deposit by for example by evaporation and highly reflective across the visible spectrum. Additionally it adheres strongly to a range of materials and is of low cost and low toxicity. A further wall is then coated at a steeper angle so that the metallisation substantially overlaps the end window, as illustrated in FIG. 9. In this diagram 1-7 are as mentioned earlier, and 8 is a transparent resin, such as a photoresist or UV curable material or other suitable material known in the art.

The fourth wall is not metallised. In this case the luminescence escapes primarily via the unmetallised (transparent) photoresist wall. The partial metallisation of the front window ensures that the pump radiation does not percolate directly through the deposit, but instead is reflected back into the phosphor deposit so as to increase its effective path-length and hence achieve better conversion efficiency. Advantageously the LEDs should be aligned so that the pump radiation enters the structure immediately above the metallised area of the front window, and as close to the metallised end wall as possible.

Optionally this process can be achieved by metallising fewer than three walls, e.g. two.

In a further embodiment the transparent slide can be coated in a suitable reflective material such as aluminium at a thickness of typically 20-40 nm so as to ensure adequate opacity, prior to photoresist deposition. After defining the well structure the reflective layer (advantageously aluminium) is removed by etching, so that it only remains in areas beneath the photoresist. Any form of etching known in the art can be used, and in the case of aluminium this could be sputtering for example using argon ions, reactive ion etching for example using an RF CCl₄ plasma, or wet chemical etching for example using a 5-10% sodium hydroxide in water solution.

The well structure is defined by walls running in the transverse and longitudinal directions. In this case either the transverse or longitudinal walls are substantially thicker than the other. The thinner walls are then metallised on both sides using angled metallisation, whereas the thicker walls are only metallised on one side. The wells are then filled with phosphor as described earlier. The metallisation on the top of the walls is then removed using any suitable process known in the art, such as an etching process as described above, or by mechanical polishing. The slide is then positioned over the LED array so that the emitting area of the LEDs is directly over the thicker walls as illustrated in FIGS. 10(a) in cross-section and 10(b) from above. In this diagram 1-8 are as described earlier. 9 is the LED array, 10 are the areas of the LED array from which light is emitted. The cover-slide and the LED array are aligned so that the emitted light enters the cover-slide via the areas marked 11 on the top of the thicker walls.

The pump radiation then illuminates the phosphor deposit from the side, with the luminescence escaping through the window immediately below the phosphor deposit.

In a further aspect of the invention the transparent slide onto which the well structure will be defined is first coated in a dichroic filter structure designed to reflect the primary (e.g. blue) radiation, but to pass the red and green luminescence. Photoresist is then deposited onto the filter structure and patterned so as to expose what will become the blue pixels, but to cover and protect what will be the red and green pixels. The filter structure is then etched away from the blue pixels, by any convenient means known in the art such as inert gas ion bombardment, reactive ion etching, wet etching or grit blasting, and the photoresist removed so as to expose the patterned filter structure. Subsequently the well structure is defined on top of this structure as described earlier and as illustrated in FIG. 11. In this 12 is the filter structure and the other annotations are as above.

The advantages of this structure are that any primary (e.g. blue) radiation that passes through the phosphor deposits and is not absorbed is reflected back into the deposit so that it does not leave the structure. This light then undergoes a double pass of the phosphor layer so that the chances of it being usefully absorbed and generating luminescence are substantially improved.

Whilst specific embodiments of the present invention have been described above, it will be appreciated that departures from the described embodiments may still fall within the scope of the present invention. For example, any suitable type of process can be used to form and fill the well structures.

1. A method for forming a color converting structure for use in conjunction with light emitting diode (LED) arrays comprising:
forming wells within or on a transparent substrate positioned over the LED arrays;
depositing an ink including a luminescent material and a binder onto the color converting structure;
setting portions of the luminescent material within the wells using the binder; and
removing excess ink that fails to be set by the binder, and wherein the portions of the luminescent material within the wells convert ultraviolet (UV) or blue light from at least a portion of LEDs of the LED arrays into other wavelengths in the visible spectrum.

2. The method according to claim 1, wherein the LED arrays emits light of the same wavelength and the portions of the luminescent material within the wells covert the light into a first light and a second light having different wavelengths.

3. (canceled)

4. The method according to claim 1, wherein the wells are defined using a photolithographic process.

5. The method according to claim 1, wherein the wells are defined using a physical process.

6. The method according to claim 1, wherein the wells are defined using reactive ion etching to transfer a photolithographically defined structure into the transparent substrate.

7. The method according to claim 1, wherein the wells are defined using reactive ion etching to transfer the photolithographically defined structure into a separate layer or layers on the transparent substrate.

8. The method according to claim 1, wherein at least a portion of the ink contained in the wells is patterned using a curing technique.

9. The method according to claim 1, wherein the binder is UV curable.

10. The method according to claim 9, wherein the binder is selectively exposed via a mask such that after development the ink is only retained in specific wells.

11. The method according to claim 9, wherein the binder is selectively exposed via a direct write approach such that after development the ink is only retained in specific wells.

12. The method according to claim 1, wherein the ink is photosensitive.

13. The method according to claim 1, wherein the wells are sequentially filled with one or more inks.

14. The method according to claim 1, wherein the ink is a positive photoresist material or a negative photoresist material.

15. The method according to claim 1, wherein prior to deposition of the ink, an internal surface of the walls of the wells are coated in a reflective material.

16. The method according to claim 15, wherein one or more walls of a well are not coated in a reflective material and a front window area of the well is at least partially coated in the reflective material.

17. The method according to claim 1, wherein:
the ink includes a photoresist;
the transparent substrate is coated in a reflective material prior to the deposition of the photoresist; and
after development of the photoresist, exposed areas of the reflective material are removed such that the one or more walls of the well are not coated in the reflective material.

18. The method according to claim 1, wherein a dichroic filter structure is deposited onto the transparent substrate and patterned using photolithography and etching processes, and wherein the wells are formed on the dichroic filter structure.

19. The method according to claim 15, wherein, the reflective material is a metallisation or high refractive index material.

20. The method according to claim 1, wherein prior to deposition of the ink, the wells are died to absorb at least a portion of the UV or blue light from the LED arrays.

21-41. (canceled)

42. An electronic display, comprising:
light emitting diode (LED) arrays configured to emit light; and
a color converting structure positioned to receive at least a portion of the light emitted from the LED arrays, including:
a transparent substrate including wells defined within or on the transparent substrate; and
a luminescent material and an insoluble binder within at least a portion of the wells to convert the at least a portion of the light transmitted through the wells of the color converting structure into other wavelengths.
